(19) United States
(12) Patent Application Publication
(10) Pub. No.: US 2004/0094412 A1
(43) Pub. Date: May 20, 2004

(54) Magnetron sputtering apparatus and magnetron sputtering method using the same

(75) Inventors: Sergiy Yakovlevich Navala, Suwon-city (KR); Dong-joon Ma, Anyang-city (KR); Tae-wan Kim, Anyang-city (KR)

Correspondence Address: LEE & STERBA, P.C., 1101 WILSON BOULEVARD, SUITE 2000, ARLINGTON, VA, 22209, US

(73) Assignee: Samsung Electronics Co., Ltd.

(21) Appl. No.: 10/306,741

(22) Filed: Nov. 29, 2002

(30) Foreign Application Priority Data
Nov. 15, 2002 (KR) 2002-71044

(51) Int. Cl. C23C 14/35

(52) U.S. Cl. 204/298.23; 204/192.12; 204/298.29; 204/298.19

(57) ABSTRACT

A magnetron sputtering apparatus and a magnetron sputtering method using the same, wherein a vacuum chamber has a discharge gas inlet and a discharge gas outlet, a substrate holder is installed inside the vacuum chamber, a magnetic circuit unit, which includes a target electrode installed opposite to the substrate and a magnetron fixed on a rear surface of the target electrode, faces the substrate holder and circulates around the central axis of the substrate holder, and a driving unit circulates the magnetic circuit unit and adjusts a distance between the target electrode and the center of the substrate holder. Accordingly, in the magnetron sputtering apparatus of the present invention, the uniformity of a thin film and the step coverage is improved.

### BACKGROUND OF THE INVENTION

1. Field of the Invention

The present invention relates to a magnetron sputtering apparatus and a magnetron sputtering method using the same. More particularly, the present invention relates to a magnetron sputtering apparatus by which a thin film is formed on a substrate in the manufacture of a semiconductor device and other electronic devices, and a magnetron sputtering method using the same.

2. Description of the Related Art

Due to an advantage of easy sputtering apparatus control, magnetron sputtering is generally used to form a thin film on a substrate in the manufacture of semiconductor devices or other electronic devices. Flat magnetron sputtering apparatuses are widely used in the manufacture of micro-electronic devices and optical devices, due to advantages such as a high deposition rate, low manufacturing cost, restriction of electron emission, and applicability to refractory metals and compounds.

In a conventional sputtering apparatus, a deposition substrate and a target, which is made of a material use to form a thin film, are disposed opposite to each other within a vacuum reaction vessel or a vacuum chamber. A discharge gas, such as argon gas, is then injected into the vacuum reaction vessel in a high vacuum state. Electrical discharge of a discharge gas is started by applying a negative voltage to the target. Due to the discharge, gas molecules are ionized into ions, which are accelerated by the negative voltage and collide with the target. The surface of the target emits atoms that are sputtered in various directions, and some of the sputtered atoms are deposited on the substrate, thereby forming a thin film. The angular distribution of the sputtered atoms follows the cosine law.

FIG. 1 illustrates a conventional sputtering apparatus. In a vacuum chamber 11, a substrate holder 14 for holding a substrate 15 is installed, and a target electrode 17 is disposed opposite to the substrate holder 14. A magnet 19 is disposed on the target electrode 17 to form magnetic field lines 20. A power supply unit 21 is installed outside the vacuum chamber 11 in order to apply a voltage to the substrate holder 14 and the target electrode 17 upon sputtering. The vacuum chamber 11 has a gas inlet 12 for receiving a discharge gas and an outlet 13 for exhausting the discharge gas or other gases in order to maintain a vacuum. The outlet 13 is used to obtain an initial high vacuum or maintain a desired degree of vacuum during sputtering, and is connected to a high-performance pump.

For a typical sputtering process, a target 18 is disposed between about 30 to 60 nm away from the substrate 15 so that target atoms emitted at a sputtering pressure of 10⁻² to 10⁻³ Pa may reach the substrate 15 without colliding with discharge gas molecules. The target 18 has a diameter 1.5 times larger than the diameter of the substrate 15. In the manufacture of semiconductor devices or other electronic devices, a target with a diameter larger than that of the substrate 15 is used, since such a target is advantageous to obtain a thin film with a uniform thickness. However, a target with a large diameter is expensive, and only a portion of the target 18 is sputtered, which is inefficient. In the case of using a small target, the uniformity of a film is decreased.

FIG. 2 is a graph showing a variation in the uniformity of a thin film formed on a fixed substrate holder by atoms emitted from the surface of an axially circular target with respect to the distance between a substrate and the target, in a conventional sputtering apparatus. Here, the uniformity is defined as in Equation 1:

$$uniformity ( \% ) = \frac{a - b}{a} \times 100 ( \% ) \qquad ( 1 )$$

wherein a denotes the thickness of a thin film at the center of a substrate, and b denotes the thickness of a thin film at the edges of the substrate. Accordingly, a smaller uniformity value indicates a more uniform deposition of a deposition material on a substrate. In an experiment, which produced the results of the graph of FIG. 2, the diameter of the circular target was 8 inches, and the diameter of the substrate was 6 inches.

Referring to FIG. 2, it may be seen from graphs f1 and f2 that the uniformity of the thickness of a thin film is improved as the distance between the target and the substrate increases. However, in a conventional sputtering apparatus, a distance within which target particles can reach the substrate without collision with discharge gas molecules is 30 to 60 mm. Consequently, the distance is not sufficient to obtain a thin film with a uniform thickness.

FIGS. 3A through 3C illustrate a process of filling fine trenches in a substrate according to a conventional sputtering method. Recently developed trenches are finer, and the fine trenches are not able to be completely filled using a typical sputtering technique. Referring to FIG. 3A, a target material 33 enters trenches 32 formed on a substrate 31 at an angle. As shown in FIG. 3B, the target material 33 is deposited around the entrance of the trench 32. Consequently, as shown in FIG. 3C, a void is formed in the trench 32 by failing to completely fill the trench 32 with the target material 33. Thus, a conventional sputtering apparatus using a target which is larger than the substrate 31 degrades the step coverage.

### SUMMARY OF THE INVENTION

The present invention provides a magnetron sputtering apparatus and a method using the same that improves the step coverage and the uniformity of the thickness of a thin film by using a small target and a large substrate.

According to a feature of an embodiment of the present invention, there is provided a magnetron sputtering apparatus in which a vacuum chamber has a discharge gas inlet and a discharge gas outlet. A substrate holder is installed inside the vacuum chamber. A magnetic circuit unit includes a target electrode installed opposite to the substrate and a magnetron installed at a rear surface of the target electrode. The magnetic circuit unit faces the substrate holder and circulates around a central axis of the substrate holder. A driving unit circulates the magnetic circuit unit and adjusts a distance between the target electrode and the center of the substrate holder.

Preferably, the substrate holder moves up and down with respect to the target electrode.

It is also preferable that the magnetic circuit unit and the substrate holder are eccentric, and the magnetic circuit unit moves in a circular path about the central axis of the substrate holder.

Preferably, the target electrode is smaller than the substrate. The size of the target electrode may be between about 20% to 50%, preferably, about 30% of the size of the substrate.

Here, the magnetron sputtering apparatus may further include a shutter installed between the substrate and the target electrode for preventing premature deposition on the substrate by shielding the target electrode.

The driving unit preferably includes a driving shaft having two ends, a bellows, and a sliding support. One end of the driving shaft is attached to the magnetic circuit unit. The bellows seals the driving shaft and repeatedly expands and contracts to move the driving shaft into and out of the vacuum chamber. The sliding support is connected to the bellows and coupled to the other end of the driving shaft to drive the driving shaft left and right, and back and forth to circulate the magnetic circuit unit.

The magnetron sputtering apparatus may further include a holder unit provided outside the vacuum chamber, which penetrates the vacuum chamber to support the magnetic circuit unit.

Preferably, the holder unit includes: a holder shaft having two ends and penetrating the vacuum chamber, one end of the holder shaft is connected to the magnetic circuit unit; and a gear unit installed outside the vacuum chamber and connected to the other end of the holder shaft to assist the circulation of the magnetic circuit unit.

The gear unit preferably includes a holder gear centered on the holder shaft and an interlocking gear that interlocks with the holder gear to transmit a driving power to the holder shaft.

Preferably, the driving shaft includes an electrical line and a cooling line, each of which penetrate the vacuum chamber and are connected to the target electrode.

The magnetron sputtering apparatus may further include an air cylinder for compensating for changes in the pressure of the vacuum chamber when the driving shaft moves into and out of the vacuum chamber.

According to another feature of an embodiment of the present invention, there is provided a magnetron sputtering method, in which, first, a magnetic circuit unit is installed inside a vacuum chamber at a predetermined distance (h) from a substrate. The magnetic circuit unit includes a target electrode that faces the substrate and a magnetron fixed to a rear surface of the target electrode. Next, a discharge gas is introduced into the vacuum chamber, the magnetic circuit unit is offset from a central axis of the substrate by a predetermined offset (A), and the magnetic circuit unit moves in a circular motion at a predetermined speed (v) around the central axis of the substrate. Thereafter, sputtered particles from the target electrode are deposited on the substrate by electrically discharging the discharge gas so that the discharge gas turns into a plasma state.

Preferably, the target electrode is smaller than the substrate. The size of the target electrode may be between about 20% to 50%, preferably, about 30% of the size of the substrate.

It is also preferable that during the magnetic circuit unit installation, a substrate holder is driven up and down to adjust the distance (h) between the magnetic circuit unit and the substrate.

Preferably, during the magnetic circuit unit circulation, the magnetic circuit unit is shielded by a shutter to prevent pre-deposition.

The uniformity of a thin film deposited on the substrate may be improved by changing the distance (h), the offset (A), and the rotation speed (v).

The step coverage of the substrate may be controlled by adjusting a time (t) for which the magnetic circuit unit is exposed and the size (s) of the target electrode.

The amount of radio frequency (RF) or direct current (DC) power may be continuously or periodically changed and applied to the magnetic circuit unit.

As described above, in the magnetron sputtering apparatus and sputtering method according to the present invention, the uniformity of a thin film deposited on the substrate can may be improved by controlling the distance (h) between the substrate and the magnetic circuit unit, the offset (A) of the magnetic circuit unit from the central shaft of the substrate, and the circulation speed (v) of the magnetic circuit unit. In addition, the step coverage of the substrate may be improved by adjusting the time (t) for which the magnetic circuit unit is exposed to a discharge gas, the distance (h) between the substrate and the magnetic circuit unit, and the size (s) of the target electrode.

### BRIEF DESCRIPTION OF THE DRAWINGS

The above and others features and advantages of the present invention will become readily apparent to those of ordinary skill in the art by the following detailed description of exemplary embodiments thereof with reference to the attached drawings in which:

FIG. 1 illustrates a schematic cross-section of a typical sputtering apparatus;

FIG. 2 is a graph showing a variation in the uniformity of a thin film formed on a fixed substrate holder with respect to the distance between a substrate and the target, in a conventional sputtering apparatus;

FIGS. 3A through 3C illustrate a process of filling fine trenches in a substrate according to a conventional sputtering method;

FIG. 4 illustrates a schematic cross-section of a magnetron sputtering apparatus according to an embodiment of the present invention;

FIG. 5A illustrates a plan view of a sputtering apparatus according to an embodiment of the present invention;

FIG. 5B illustrates a side view of a sputtering apparatus according to an embodiment of the present invention;

FIG. 6 illustrates the driving principle of a sputtering apparatus according to an embodiment of the present invention;

FIGS. 7A and 7B illustrate cross-sectional views for explaining a process of depositing target particles on a substrate with trenches using a sputtering apparatus and method according to an embodiment of the present invention;

FIG. 8 is a graph showing a variation in the thickness of a thin film with respect to locations from the center of a substrate, when a sputtering apparatus and sputtering method are used under conditions of a first exemplary embodiment of the present invention to form the thin film; and

FIG. 9 is a graph showing a variation in the thickness of a thin film with respect to locations from the center of a substrate, when a sputtering apparatus and sputtering method are used under conditions of a second exemplary embodiment of the present invention to form the thin film.

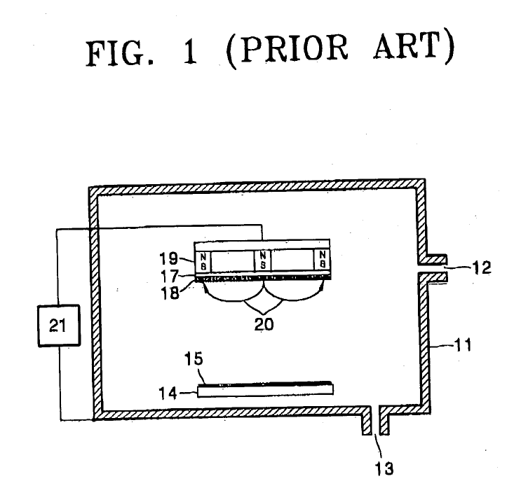

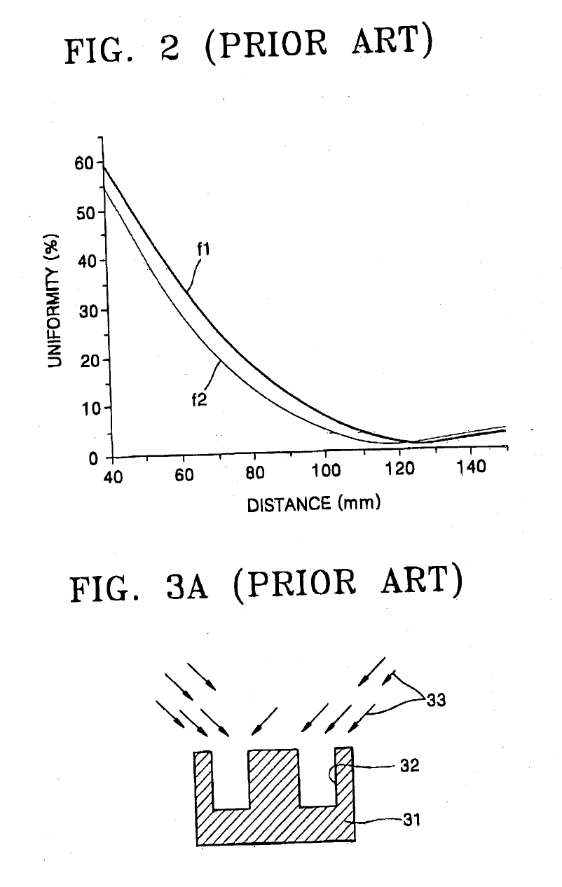

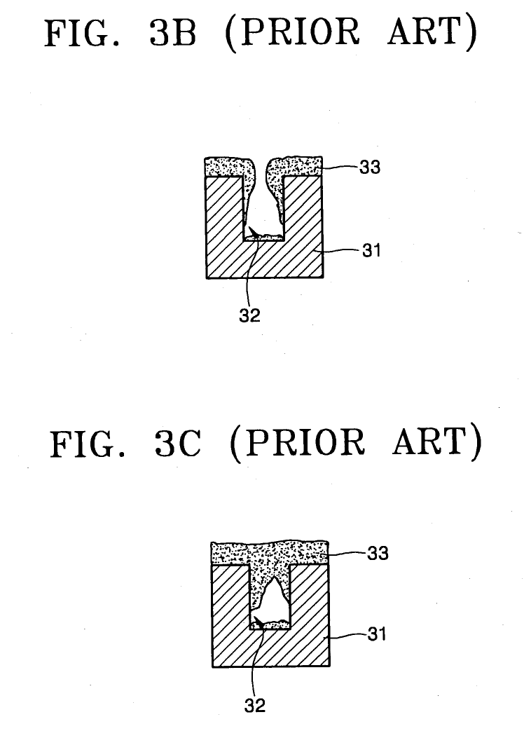

### DETAILED DESCRIPTION OF THE INVENTION

Korean Patent Application No. 2001-30771, filed Jun. 1, 2001, and entitled: “Magnetron Sputtering Apparatus and Method,” and Korean Patent Application No. 2002-71044, filed Nov. 15, 2002, and entitled: “Magnetron Sputtering Apparatus and Method,” are incorporated by reference herein in their entirety.

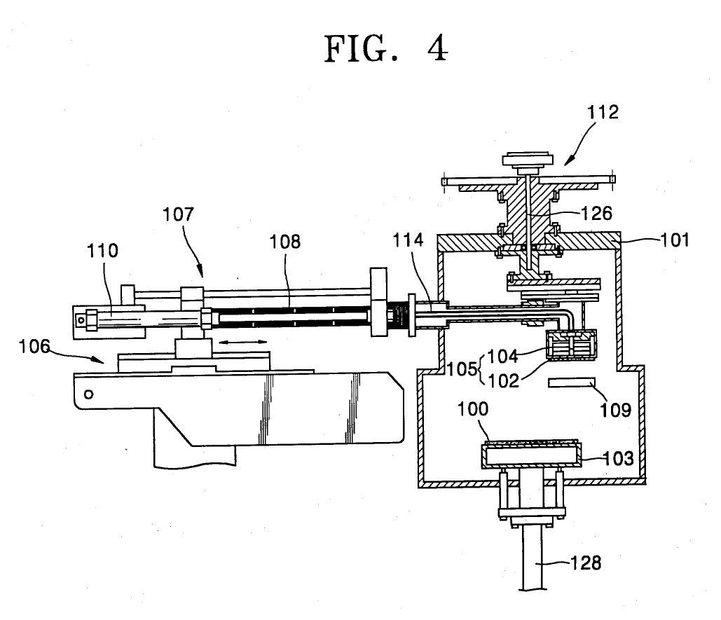

FIG. 4 illustrates a schematic cross-section of a magnetron sputtering apparatus according to an embodiment of the present invention. Referring to FIG. 4, a vacuum chamber 101 has a discharge gas inlet (not shown) and a discharge gas outlet (not shown), and a driving unit 107, which is connected to a magnetic circuit unit 105 inside the vacuum chamber 101 to circulate the magnetic circuit unit 105, is provided outside the vacuum chamber 101. A substrate holder 103 for holding a substrate 100 is located within a lower space of the vacuum chamber 105. A support shaft 128 for supporting the substrate holder 103 penetrates the vacuum chamber 101 and moves the substrate holder 103 up and down in order to control the distance between the substrate holder 103 and the magnetic circuit unit 105. The magnetic circuit unit 105 and the substrate 100 face each other and are eccentric. The magnetic circuit unit 105 includes a target electrode 102 made of a material to be deposited on the substrate 100 and a plurality of magnetrons 104 fixed to the rear surface of the target electrode 102.

In order to prevent pre-deposition of particles sputtered from the target electrode 102 on the substrate 100, a shutter 109 is installed between the substrate 100 and the target electrode 102.

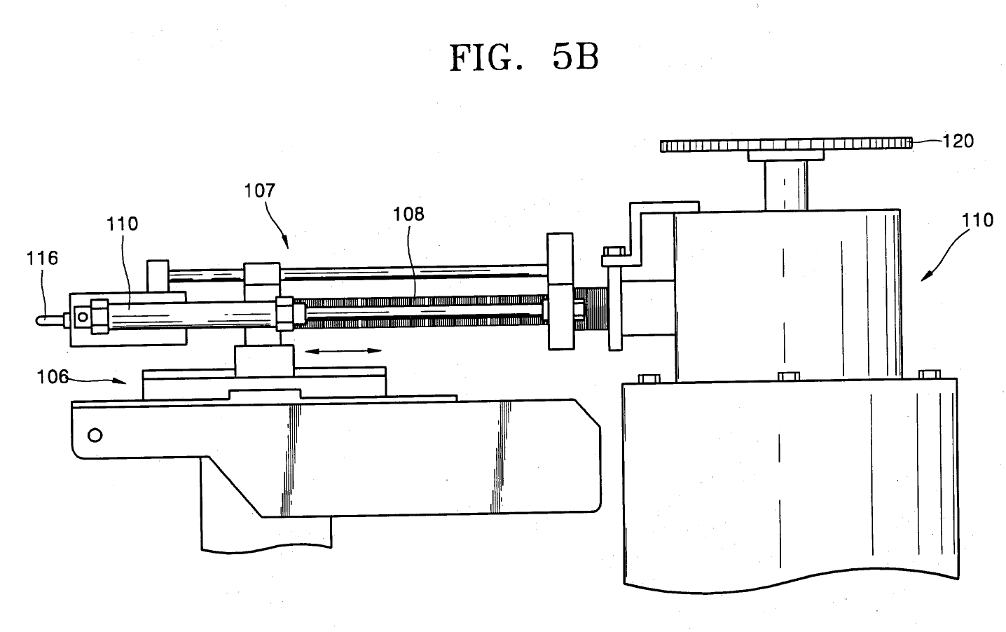

During a sputtering mechanism in a sputtering apparatus according to the present invention, first, the vacuum chamber 101 is pumped out to keep a vacuum state of a predetermined pressure. Then, a discharge gas flows into the vacuum chamber 101 through the discharge gas inlet, and a voltage from an external source is applied to the target electrode 102. When electric discharge of a discharge gas occurs on the surface of the target electrode 102, plasma gas ions transmit energy to the target electrode 102 by colliding with the target electrode 102. While the lattice structure of the target electrode 102 is disintegrated, ions are detached from the target electrode 102. While the discharge gas is discharged, simultaneously the magnetic circuit unit 105 moves in a circular motion along a predetermined path, target particles are deposited on the substrate 100 by controlling several parameters to obtain a certain deposition profile. In the process of deposition, the amount of radio frequency (RF) or direct current (DC) power may be changed continuously or periodically. The sputtering performed by controlling several parameters will be described in detail in connection with the description of FIG. 6.

When the shutter 109 closes, deposition occurs on the shutter 109 instead of the substrate 100. Thus, the target electrode 102 is cleaned, and a deposition is stabilized. When the shutter 109 opens, deposition occurs on the substrate 100, and the magnetic circuit unit 105 moves in a circular motion so that it returns to the same location under over the shutter 109 in a deposition cycle. An area where the shutter 109 is located serves as a parking area of the magnetic circuit unit 105.

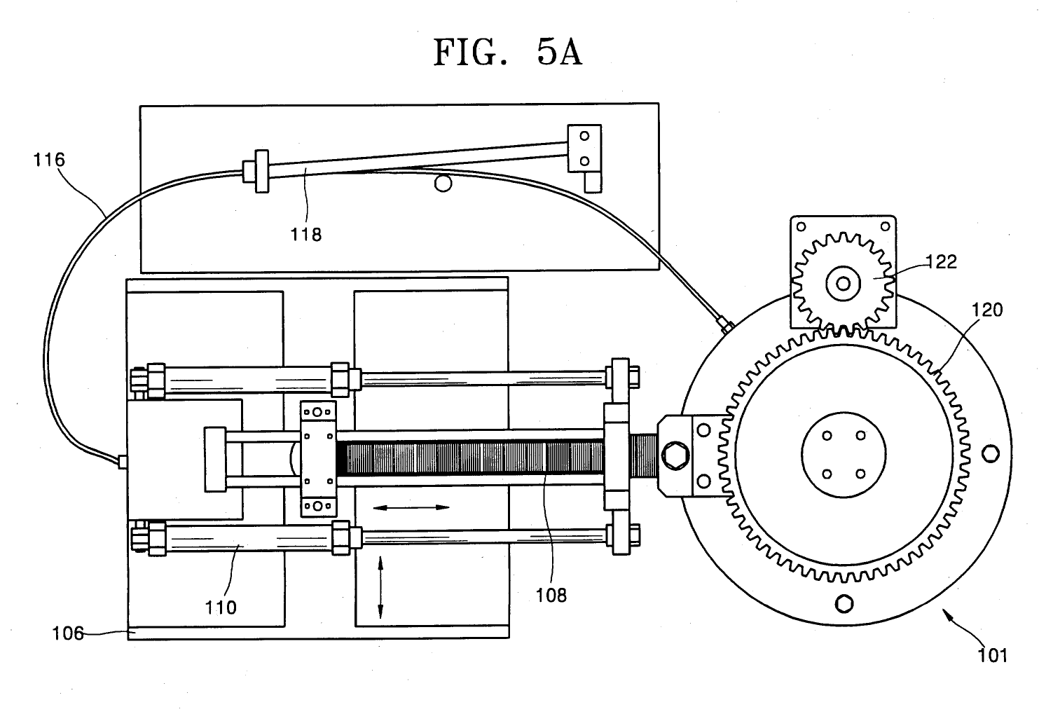

FIGS. 5A and 5B illustrate a plan view and a side view, respectively, of a sputtering apparatus according to an embodiment of the present invention.

Referring to FIGS. 4, 5A, and 5B, the driving unit 107 includes a driving shaft 114 for holding and circulating the magnetic circuit unit 105.

The driving shaft 114 penetrates the vacuum chamber 101 and is coupled to an external sliding support 106. The sliding support 106 is driven left and right, and back and forth by a motor (not shown) and accordingly rotates the driving shaft 114 at a predetermined speed and at a predetermined circulation diameter.

The driving shaft 114 is sealed with a bellows 108. The bellows 108 repeatedly expands and contracts along with the back and forth movement of the sliding support 106. Hence, the driving shaft 114 is driven backwards and forwards and accordingly moves into or out of the vacuum chamber 101. Air cylinders 110 are further installed at both sides of the driving shaft 114 to compensate for a pressure difference in the vacuum chamber 101 due to the inward and outward movement of the driving shaft 114. The air cylinders 110 pump air into or out of the vacuum chamber 101 while the driving shaft 114 circulates the magnetic circuit unit 105, thereby offsetting the internal pressure of the vacuum chamber 101 caused by the inward and outward motion of the driving shaft 114. The internal pressure of the vacuum chamber 101 is maintained at about 0.1 to 1 Pa.

A holder unit 112 is installed over the vacuum chamber 101 and supports the magnetic circuit unit 105 located inside the vacuum chamber 101. A holder shaft 126 connected to the magnetic circuit unit 105 is installed at the center and on the inside of the holder unit 112. A gear unit is installed outside the vacuum chamber 101 and connected to the holder shaft 126 to assist the circulation of the magnetic circuit unit 105. The gear unit has a holder gear 120 and an interlocking gear 122, which interlocks with the holder gear 120 to transmit a driving power to the holder shaft 126. Reference numeral 116 denotes a discharge gas line, and reference numeral 118 denotes a discharge gas line support.

FIG. 6 illustrates the driving principle of the sputtering apparatus according to an embodiment of the present invention. The target electrode 102, which is smaller than the substrate 100, deposits a uniform film on the substrate 100 while circulating around the central axis of the substrate 100. The uniformity of a film deposited on the substrate 100 has a direct effect on the physical characteristics of the film. More particularly, if multiple layers are deposited or a device is manufactured, a uniformity thereof greatly affects the properties of the multiple layers or device. Hence, it is very important to uniformly control the thickness of a deposited film. If a film with a thickness similar to a molecular size is deposited on the substrate 100, even a fine protrusion can significantly degrade a surface roughness.

Given that the radius of the substrate 100 is indicated by R, the distance between the substrate 100 and the target electrode 102 is indicated by h, an offset of the target electrode 102 from the central axis of the substrate 100 is indicated by A, the total mass of sputtered particles is indicated by m, and the mass density of the target electrode 102 is indicated by ρ, the thickness of a film deposited on the substrate 100 is calculated using Equation 2:

$$t ( A ) = \frac{m {h}^{2}}{ρ π} \frac{{h}^{2} + {A}^{2} + {R}^{2}}{{( {h}^{2} + {A}^{2} + {R}^{2} + 2 A R )}^{3 / 2} {( {h}^{2} + {A}^{2} + {R}^{2} - 2 A R )}^{3 / 2}} \qquad ( 2 )$$

When multi-offset motions are made, Equation 3 is obtained from Equation 2, under an assumption that the thickness of the film deposited on the substrate 100 is the sum of the thickness values of multiple films obtained by multi-offset motions:

$$t ( d , h , τ , d ) = \frac{m {h}^{2} τ}{ρ {π}^{2}} {\int }_{0}^{π} \frac{ψ ( h , A , d , R , θ )}{\begin{matrix}[ ψ ( h , A , d , R , θ ) + 2 {A ( {Θ ( d , r , θ )}^{1 / 2} ]}^{3 / 2} \cdot \\ [ ψ ( h , A , d , R , θ ) - 2 {A ( {Θ ( d , r , θ )}^{1 / 2} ]}^{3 / 2}\end{matrix}} \qquad ( 3 )$$

wherein Θ(d,r, θ)=d²+r²+2dr cos θ, Ψ(h,A,d,r, θ)=h²+A²+Θ(d,r, θ), τ denotes a deposition duration (sec), and d denotes an offset (mm) of the magnetrons.

In a sputtering method according to the present invention, the substrate holder 103 for holding the substrate 100 controls the distance h between the substrate 100 and the target electrode 102 by moving up and down. The offset A of the center of the target electrode 102 from the central axis of the substrate 100 is controlled by moving the driving shaft 114 into or out of the vacuum chamber 101. At the same time, the driving speed v of the target electrode 102 is controlled. In this way, the uniformity of a film deposited on the substrate 100 is improved.

In addition, the size of the target electrode 102 is adjusted to be about 20% to 50%, preferably, about 30% of the size of the substrate 100 so as to improve the uniformity of a target material deposited on the substrate 100 and enhance step coverage.

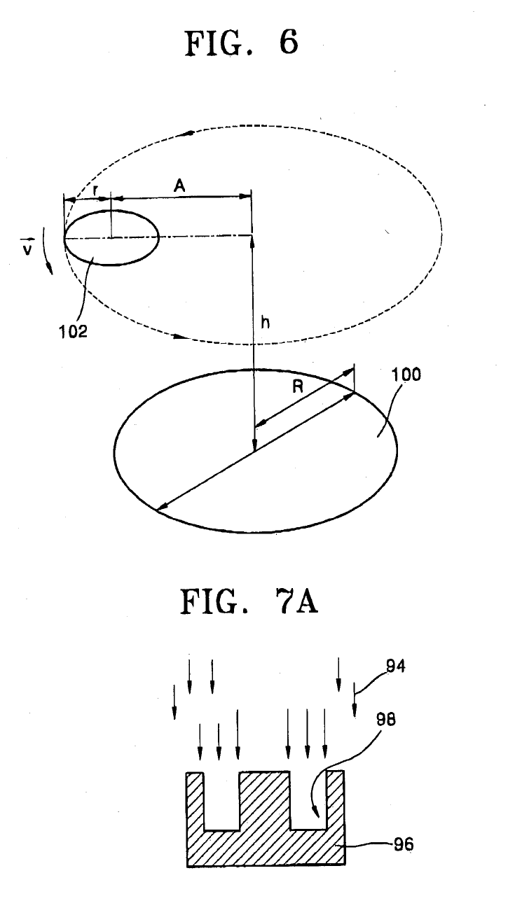

FIGS. 7A and 7B illustrate cross-sectional views for explaining a process of depositing target particles 94 on a substrate 96 with trenches using a sputtering apparatus and method according to an embodiment of the present invention. Referring to FIG. 7A, a plurality of trenches 98 are formed in a substrate 96. Over the trenches 98, ions of an inert gas, such as argon gas in a plasma state, collide with a target electrode. Target particles 94, which are detached from the target electrode due to collisions, are deposited on the substrate 96. Since the target electrode 102 is smaller than the substrate 100, the detached target particles 94 are almost vertically incident upon the trenches 98, unlike in a conventional deposition method in which target particles are incident to the trenches at an angle. Hence, as shown in FIG. 7B, the target particles 94 are deposited to a uniform thickness over the entire surface of the trenches 98 of the substrate 96 including the surface of a step difference portion. Consequently, a thin film 94a having an improved thickness uniformity and an improved step coverage is formed.

In particular, the step coverage can be improved by adjusting the radius (r) of a target electrode, the distance (h) between a substrate and a target electrode, and the time (t) for which the target electrode is exposed. The time (t) can be controlled by opening a shutter.

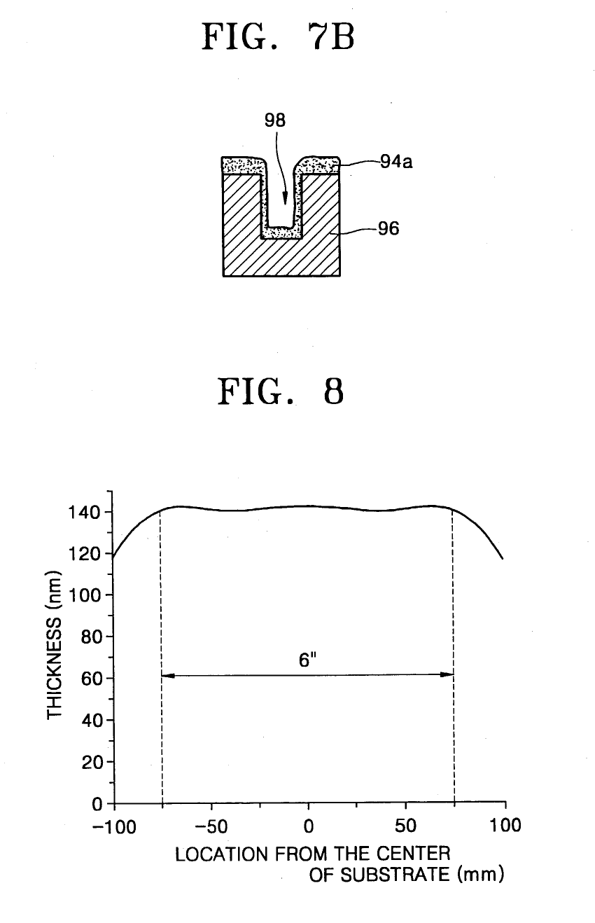

FIG. 8 is a graph showing a variation in the thickness of a thin film with respect to locations from the center of a substrate, when a sputtering apparatus and a sputtering method are used under conditions of a first exemplary embodiment of the present invention to form the thin film. Under the conditions of the first exemplary embodiment, the mass of a sputtered material is set to be 5 g, the mass density of the sputtered material is set to be 2.7 g/cm³, the radius of a magnetron is set to be 25 mm, the diameter of a substrate is set to be 150 mm, the distance between a target electrode and the substrate is set to be 50 mm, and the rotation speed of the target electrode is set to be 10 rpm. Under the above settings, first, an offset of the target electrode from the central axis of the substrate is set to be 107 mm, and then the target electrode is exposed for 43 seconds. Thereafter, the offset is set be 85 mm and then the target electrode is exposed for 137 seconds. Then, the offset is changed to 3 mm and then the target electrode is exposed for 20 seconds.

Referring to FIG. 8, since the thickness profile of a thin film has an error range of no more than 0.83%, the uniformity of the thin film is greatly improved.

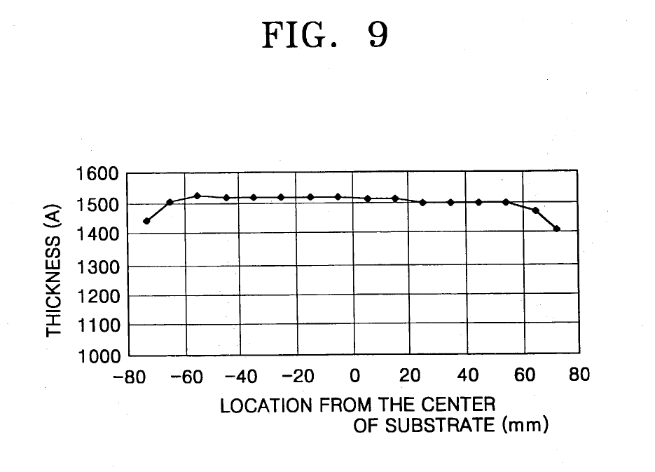

FIG. 9 is a graph showing a variation in the thickness of a thin film with respect to locations from the center of a substrate, when a sputtering apparatus and sputtering method are used under conditions of a second exemplary embodiment of the present invention to form the thin film. Under the conditions of the second exemplary embodiment, the radius of a magnetron is set to be 2 inches, and the diameter of a substrate is set to be 6 inches. Under the above setting, first, the distance between a target electrode and a substrate is set to be 60 mm, and an offset of the target electrode from the central axis of the substrate is set to be 20 mm. In this state, the target electrode is exposed for 336 seconds. Thereafter, the distance between the target and the substrate is changed to 40 mm, and the offset is adjusted to be 74 mm. In this state, the target electrode is exposed for 432 seconds. Then, the distance between the target electrode and the substrate is changed to 4 mm without any change in the offset, and then the target electrode is exposed for 432 seconds.

Referring to FIG. 9, since the thickness profile of a thin film has an error range not exceeding 2.8%, the uniformity of the thin film is greatly improved.

In a magnetron sputtering apparatus and method according to the present invention, a thin film is deposited to a uniform thickness on a large substrate using a target electrode smaller than a substrate and a driving unit that can control parameters (e.g., distance, offset, rotation speed, or exposure time) while circulating the target electrode with respect to the substrate. In addition, the step coverage of trenches is improved.

As described above, a sputtering apparatus according to the present invention can improve the uniformity of a thin film and the step coverage of trenches by employing a driving unit that can circulate a target electrode smaller than a substrate around the substrate. A sputtering method according to the present invention can improve the uniformity of a thin film by controlling parameters, such as, distance between a substrate and a target electrode, offset of the target electrode from the central axis of the substrate, and rotation speed of the target electrode. In addition, the step coverage of a substrate with trenches can be improved by controlling parameters, such as, the distance of the substrate and the target electrode, exposure time of the target electrode, and the radius of the target electrode.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A magnetron sputtering apparatus including:
a vacuum chamber in which a discharge gas inlet and a discharge gas outlet are formed;
a substrate holder for holding a substrate installed inside the vacuum chamber;
a magnetic circuit unit including a target electrode installed opposite to the substrate and a magnetron installed at a rear surface of the target electrode, wherein the magnetic circuit unit faces the substrate holder and circulates around a central axis of the substrate holder; and
a driving unit for circulating the magnetic circuit unit and for adjusting a distance between the target electrode and the center of the substrate holder.

2. The magnetron sputtering apparatus as claimed in claim 1, wherein the substrate holder moves up and down with respect to the target electrode.

3. The magnetron sputtering apparatus as claimed in claim 1, wherein the magnetic circuit unit and the substrate holder are eccentric, and the magnetic circuit unit moves in a circular path about the central axis of the substrate holder.

4. The magnetron sputtering apparatus as claimed in claim 1, wherein the target electrode is smaller than the substrate.

5. The magnetron sputtering apparatus as claimed in claim 4, wherein the size of the target electrode is between about 20% to 50% of the size of the substrate.

6. The magnetron sputtering apparatus as claimed in claim 5, wherein the size of the target electrode is about 30% of the size of the substrate.

7. The magnetron sputtering apparatus as claimed in claim 1, further comprising a shutter installed between the substrate and the target electrode for preventing premature deposition on the substrate by shielding the target electrode.

8. The magnetron sputtering apparatus as claimed in claim 1, wherein the driving unit comprises:
a driving shaft having two ends, one end of which is attached to the magnetic circuit unit;
a bellows for sealing the driving shaft and repeatedly expanding and contracting to move the driving shaft into and out of the vacuum chamber; and
a sliding support connected to the bellows and coupled to the other end of the driving shaft to drive the driving shaft left and right, and back and forth to circulate the magnetic circuit unit.

9. The magnetron sputtering apparatus as claimed in claim 1, further comprising a holder unit provided outside the vacuum chamber, which penetrates the vacuum chamber to support the magnetic circuit unit.

10. The magnetron sputtering apparatus as claimed in claim 9, wherein the holder unit comprises:
a holder shaft penetrating the vacuum chamber, one end of which is connected to the magnetic circuit unit; and
a gear unit installed outside the vacuum chamber and connected to the other end of the holder shaft to assist the circulation of the magnetic circuit unit.

11. The magnetron sputtering apparatus as claimed in claim 10, wherein the gear unit comprises:
a holder gear centered on the holder shaft; and
an interlocking gear which interlocks with the holder gear to transmit a driving power to the holder shaft.

12. The magnetron sputtering apparatus as claimed in claim 8, wherein the driving shaft comprises an electrical line and a cooling line, each of which penetrate the vacuum chamber and are connected to the target electrode.

13. The magnetron sputtering apparatus as claimed in claim 8, further comprising an air cylinder for compensating for changes in the pressure of the vacuum chamber when the driving shaft moves into and out of the vacuum chamber.

14. A magnetron sputtering method comprising:
installing a magnetic circuit unit inside a vacuum chamber at a predetermined distance (h) from a substrate, the magnetic circuit unit including a target electrode that faces the substrate and a magnetron fixed to a rear surface of the target electrode;
introducing a discharge gas into the vacuum chamber, offsetting the magnetic circuit unit from the central axis of the substrate by a predetermined offset (A), and circulating the magnetic circuit unit at a predetermined speed (v) around a central axis of the substrate; and
depositing sputtered particles from the target electrode on the substrate by electrically discharging the discharge gas so that the discharge gas turns into a plasma state.

15. The magnetron sputtering method as claimed in claim 14, wherein the target electrode is smaller than the substrate.

16. The magnetron sputtering method as claimed in claim 15, wherein the size of the target electrode is between about 20% to 50% of the size of the substrate.

17. The magnetron sputtering method as claimed in claim 16, wherein the size of the target electrode is about 30% of the size of the substrate.

18. The magnetron sputtering method as claimed in claim 14, wherein during the magnetic circuit unit installation, a substrate holder is driven up and down to adjust the distance (h) between the magnetic circuit unit and the substrate.

19. The magnetron sputtering method as claimed in claim 14, wherein during the magnetic circuit unit circulation, the magnetic circuit unit is shielded by a shutter to prevent pre-deposition.

20. The magnetron sputtering method as claimed in claim 14, wherein the uniformity of a thin film deposited on the substrate is improved by changing the distance (h), the offset (d), and the rotation speed (v).

21. The magnetron sputtering method as claimed in claim 14, wherein the step coverage of the substrate is controlled by adjusting a time (t) for which the magnetic circuit unit is exposed and the size (s) of the target electrode.

22. The magnetron sputtering method as claimed in claim 14, wherein the amount of radio frequency (RF) or direct current (DC) power is continuously or periodically changed and applied to the magnetic circuit unit.
